(19) United States
(12) Patent Application Publication
(10) Pub. No.: US 2019/0067378 A1
(43) Pub. Date: Feb. 28, 2019

(54) LIGHT EMITTING DEVICE

(71) Applicant: INT TECH CO., LTD., HSINCHU COUNTY (TW)

(72) Inventor: CHIEN-YU CHEN, TAOYUAN CITY (TW)

(21) Appl. No.: 15/689,384

(22) Filed: Aug. 29, 2017

(51) Int. Cl. H01L 27/32; H01L 51/56; H01L 33/08

(52) U.S. Cl. CPC H01L 27/322; H01L 33/08; H01L 51/56

(57) ABSTRACT

A light emitting device includes a light emitting layer. The light emitting layer includes a plurality of light emitting cells and a plurality of color filters. Each of the plurality of color filters is over a corresponding one of the plurality of light emitting cells according to wavelength emitted by the corresponding one light emitting cell.

### TECHNICAL FIELD

The present disclosure is related to light emitting device, especially to an organic light emitting device and manufacturing method thereof.

### BACKGROUND

Flat panel display becomes more popular in recent years and is widely adopted from pocket sized electronic devices, such as cell phone, to a wall mount big screen television. Similar to the increasing demanding on the transistor density for IC (Integrated Circuit), the resolution requirement for a display has also been elevated. In recent trend, organic light emitting material is introduced as a light source in flat panel to enhance the possibility of foldability.

### SUMMARY

A light emitting device includes a light emitting layer. The light emitting layer includes a plurality of light emitting cells and a plurality of color filters. Each of the plurality of color filters is over a corresponding one of the plurality of light emitting cells according to wavelength emitted by the corresponding one light emitting cell.

In the light emitting device, a lateral width of one of the plurality of light emitting cells is not greater than about 5 um. In the lighe emitting device, each of the plurality of light emitting cells is made with an organic light emittting material. The light emitting device comprisies a substrate, wherein one of the plurality of light emitting cells are in a recess of the substrate. The lighe emitting device, wherein one of the plurality of light emitting cells has a protrusion between about 0.2 um and 2 um measured from a top surface of the substrate.

In the light emitting device, wherein one of the plurality of color filters has a lateral width being substantially equal to that of the corresponding one light emitting cell. In the light emitting device of, wherein a geometric center of one of the plurality of color filters substantially coincides with a geometric center of the corresponding one light emitting cell. In the light emitting device, wherein one of the plurality of color filters is in direct contact with the corresponding one light emitting cell.

The light emitting device of comprises a polymeric layer between one of the plurality of color filters and the corresponding one light emitting cell. In the light emitting device the polymeric layer includes fluorine. In the light emitting device, the polymeric layer includes graphene.

A light emitting device comprises a substrate, a light emitting layer over the substrate, and an encasulation layer covering the light emitting layer. The light emitting layer comprises an array of light emitting units. Each light emitting unit comprises an organic light emitting cell and a color filter over the organic light emitting cell. The substrate includes graphene. The encapsulation layer includes graphene. The light emitting device comprises a barrier layer, wherein the barrier layer is harder than the encasulation layer. The light emitting layer is sealed by the encapsulation layer.

A light emitting device includes a substrate, a light emitting layer over the substrate, and a cap layer covering the light emitting layer. The light emitting layer comprises an array of light emitting units, wherein each light emitting unit comprises an organic light emitting cell and a color filter over the organic light emitting cell. The cap layer includes a polymeric encapsulation layer and an inorganic barrier layer. The color filter is over the cap layer.

### BRIEF DESCRIPTION OF THE DRAWINGS

FIG. 1 is a flexible light emitting device.

FIG. 2 is top view of a portion of a flexible light emitting device according to an embodiment.

FIG. 3 is cross sectional view of a portion of a flexible light emitting device according to an embodiment.

FIG. 3a is cross sectional view of a portion of a flexible light emitting device according to an embodiment.

FIGS. 4a-4b illustrate a patterning operation forming color filter over a light emitting cell.

FIG. 5 is cross sectional view of a portion of a flexible light emitting device according to an embodiment.

FIG. 6 is cross sectional view of a portion of a flexible light emitting device according to an embodiment.

FIGS. 6a-6b are cross sectional views of a portion of a flexible light emitting device according to some embodiments.

FIG. 7a is a spin coating operation.

FIG. 7b is cross sectional view of a portion of a flexible light emitting device according to an embodiment.

FIG. 8a is an jet spraying operation.

FIG. 8b is cross sectional view of a portion of a flexible light emitting device according to an embodiment.

FIG. 9 is cross sectional view of a portion of a flexible light emitting device according to an embodiment.

### DETAILED DESCRIPTION OF THE DISCLOSURE

The present disclosure is to introduce a method being capable of manufacturing a high density light emitting display. In the disclosure, the term “high density” is defined as the lighting pixel density is at least equal or greater than 800 ppi. However, the method is also applied for light emitting display with pixel density lower than 800 ppi.

The present disclosure is to provide a new design of an electrode for an organic light emitting material used in a flexible panel. The electrode has a suitable dimension is order to minimize the reflection of the ambient light. Material of the electrode also has a high flexibility and low resistivity so as to make the flexible panel foldable and low power consumption. Through the present disclosure, a flat panel designer can have a much greater window to allocate the driving circuit, touch panel wires within the light emitting pixel array.

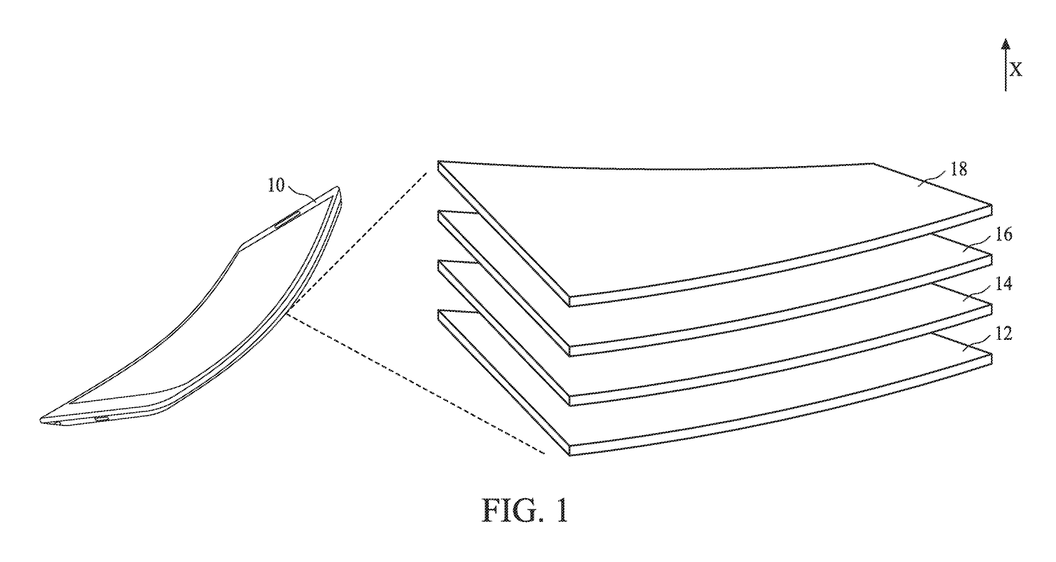

FIG. 1 illustrates an embodiment of an electronic device 10. The electronic device 10 can be a rigid or a flexible display. Display 10 can have at least four different layers substantially stacked along a thickness direction X. Layer 12 is a substrate configured as a platform to have a display layer 14 disposed thereon. Layer 16 is a cap layer to be disposed on the light emitting layer 14 and layer 18 is configured as a window for light emitting in/out the electronic device 10. In some embodiments, layer 16 is an encapsulation layer. Layer 18 can also be configured as a touch interface for the user, therefore the surface hardness of the might be high enough to meet the design requirement. In some embodiments, layer 16 and layer 18 are integrated into one layer.

Layer 12 might be formed with a polymer matrix material. Layer 12 has a bend radius being not greater than about 3 mm. In some embodiments, layer 12 has a minimum bend radius being not greater than 10 mm. The minimum bend radius is measured to the inside curvature, is the minimum radius one can bend layer 12 without kinking it, damaging it, or shortening its life. In some embodiments, several conductive traces may be disposed in layer 12 and form circuitry to provide current to the light emitting layer 14. In some embodiments, layer 12 includes graphine.

In some embodiments, a thin film transistor (TFT) is disposed on layer 12 and located between layer 12 and light emitting layer 14. In some embodiments, the TFT can be embedded into layer 12 and integrated as a whole. In some embodiments, the layer 12 includes graphene.

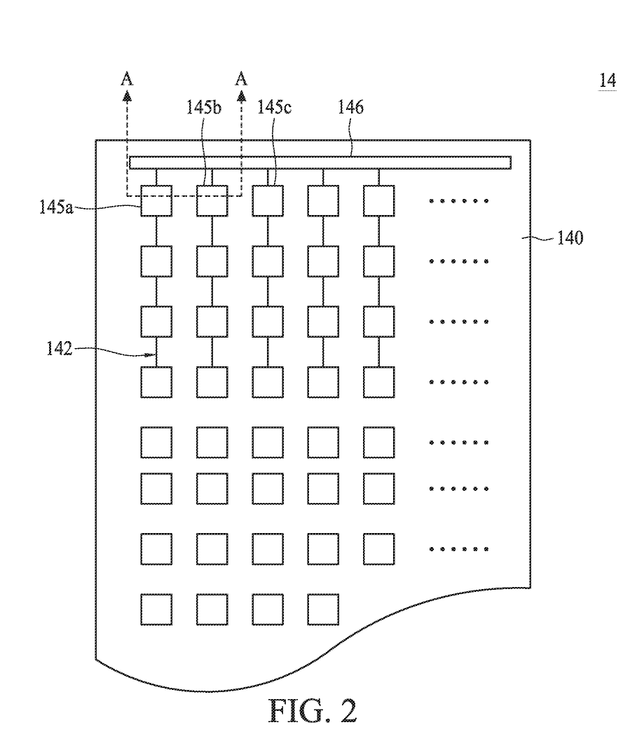

FIG. 2 is a top view of the light emitting layer 14 in one embodiment. The light emitting layer 14 has a surface 140. An array of light emitting units including light emitting unit 145a, 145b, and 145c disposed on the surface 140. Each light emitting unit is supplied with current through conductive trace 142. In one embodiment, some light emitting units such in a column and connected in series by the conductive trace 142. The light emitting units can be further electrically coupled with an electrode 146. The electrode 146 may be disposed at a peripheral region of the surface 140.

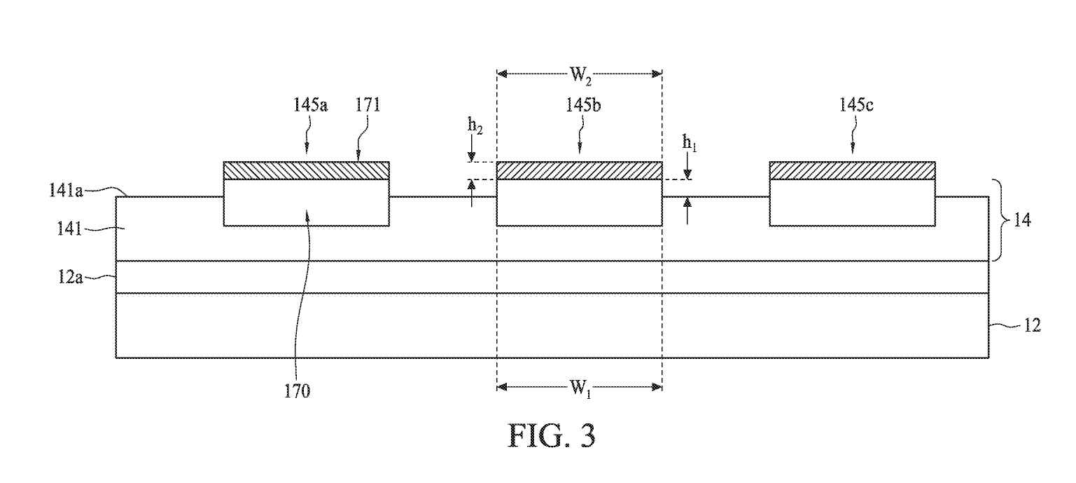

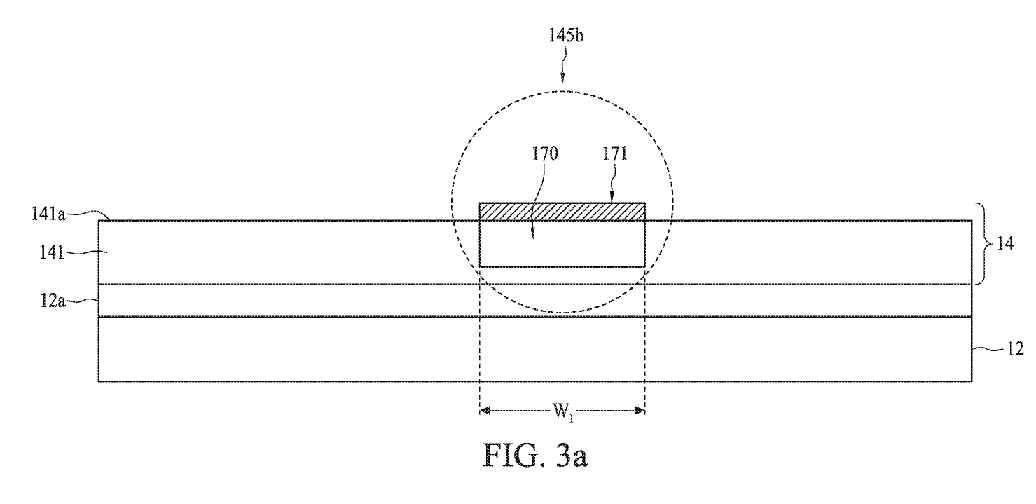

FIG. 3 is a cross sectional view along line AA in FIG. 2. A layer 12a having TFT or other circuitries can be disposed on the substrate 12. Light emitting layer has a matrix 141. In some embodiments, matrix 141 includes polymeric material. In some embodiments, matrix 141 includes graphene. Light emitting units, 145a, 145b, 145c, are embedded in the matrix 141. In some embodiments, matrix 141 has a hardness of H₁, which is greater the a hardness H₂ of the light emitting units. In some embodiments, the matrix 141 includes light absorbing material, which is opaque to light within an range of 400 nm-700 nm. In some embodiments, the substrate is opaque to light emitting from one of the light emitting units 145a, 145b, 145c, in order to reduce the interference between adjacent light emitting units.

Each light emitting unit includes a light emitting cell 170 and a color filter 171. In some embodiments, the light emitting cell 170 is made with an organic light emittting material In some embodiments, the color filter 171 is configured to correspond to the light emitting cell 170. In some embodiments, the color filter 171 is in direct contact with the light emitting cell 170. For example, if the light emitting cell 170 is configured to emit a light within a first wavelength range, the color filter 171 is configured to be transparent to the light within the first wavelength range. Any light with wavelength beyond the first wavelength range is blocked by the color filter 171.

In some embodiments, the light emitting cell 170 of light emitting unit 145a is configured to emit a light within a first wavelength range. In some embodiments, the light emitting cell 170 of light emitting unit 145b is configured to emit a light within a second wavelength range. In some embodiments, the light emitting cell 170 of light emitting unit 145c is configured to emit a light within a third wavelength range. In some embodiments, the light emitting cell 170 of light emitting unit 145a is configured to emit a red light. In some embodiments, the light emitting cell 170 of light emitting unit 145b is configured to emit a green light. In some embodiments, the light emitting cell 170 of light emitting unit 145c is configured to emit a blue light.

A light emitting cell 170 has a lateral width W₁. In some embodiments, W₁ is not greater than about 5 um. In some embodiments, W₁ is between about 3 um and about 5 um. In some embodiments, W₁ can be smaller than 1 um. In some embodiments, W₁ can be smaller than 0.1 um. In some embodiments, W₁ can be smaller than 0.01 um. In the present disclosure, to width W₁ can be adjusted according to the requirement of the PPI. For some ultra high PPI (over 1000 or even over 2000) device, the width W₁can be decreased 0.2 to micron or even submicron scale.

A light emitting cell 170 has a vertical pertrusion h₁ that is above the surface 141a of the opaque matrix 141. The protrusion h₁ can be between 0.2 and 2 um. When h₁ equals 0, the top surface of the light emitting cell 170 is substantially coplanar with the surface 141a of the opaque matrix 141.

In some embodiments, the light emitting cell 170 is recessed under the surface 141a of the opaque matrix 141 as depicted in FIG. 3a. In such case, h1 is zero or negative. The sidewall of the light emitting cell 170 is surrounded or enclosed by the opaque matrix 141.

The color filter 171 has a lateral width W₂. In some embodiments, width W₂ is designed to be in corresponding to the width W₁ of the light emitting cell 170. In some embodiments, width W₂ is designed to be substantially equal to the width W₁ of the light emitting cell 170. In some embodiments, width W₂ is designed to be about 90-99% of the width W₁ of the light emitting cell 170. In some embodiments, width W₂ is designed to be about 90-110% of the width W₁ of the light emitting cell 170. In some embodiments, width W₂ is designed to be about 101-110% of the width W₁ of the light emitting cell 170.

In some embodiments, the W₂ is between about 3 um and about 5 um. In some embodiments, W₁ can be smaller than 1 um. In some embodiments, W₁ can be smaller than 0.1 um. In some embodiments, W₁ can be smaller than 0.01 um. In the present disclosure, to width W₁ can be adjusted according to the requirement of the PPI.

The color filter 171 has a thickness h₂. In some embodiments, the thickness h₂ can be between 1 and 20 um.

In one embodiment, the color filter 171 is formed on the the light emitting cell 170 by a photo lithography process. In one embodiment, the color filter 171 is formed by disposing a layer of light filter material over the light emitting cell 170 and the surface 141a. In one embodiment, the color filter 171 is formed by removing light filter material from the surface 141a and only a portion that is over the light emitting cell 170 remains.

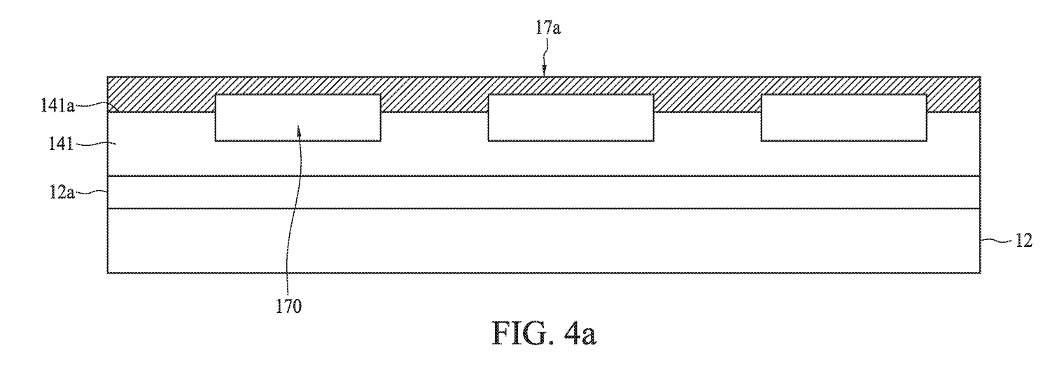

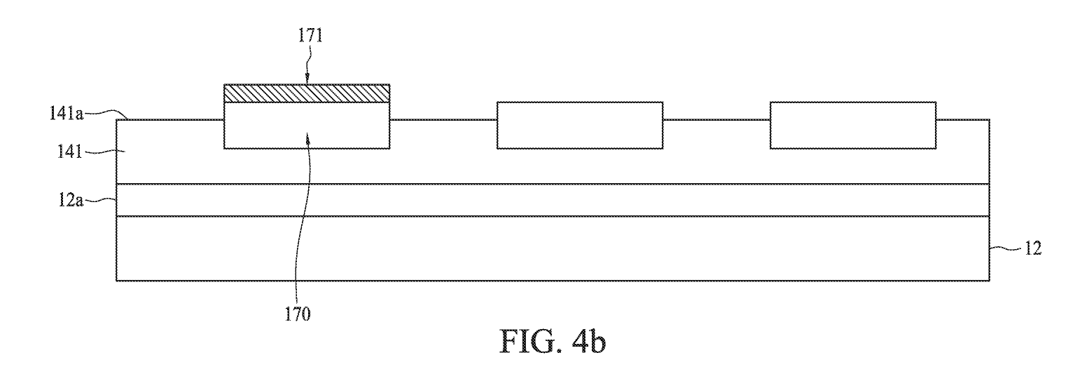

The color filter can be formed through a patterning operation. In some embodiments, the patterning operation is a photo lithography process or laser carving. FIGS. 4a-4c illustrate an operation of forming three different types color filter over the light emitting units.

In FIG. 4a, by disposing a color filtering material 17a over the light emitting cell and the surface 141a of the opaque matrix 141 as in FIG. 4a. The color filtering material 17a is transparent to the light within the first wavelength range. In FIG. 4b, a patterning operation is performed to partially remove color filtering material hence only a portion 171 remians on the first light emitting cell 170.

Similar operation can be repeated with different types of color filtering material for other light emitting cells. For example, a second type color filtering material, which is transparent to the light within the second wavelength range is blanket disposed over the opaque matrix 141 and then patterned to remain over second type light emitting cells.

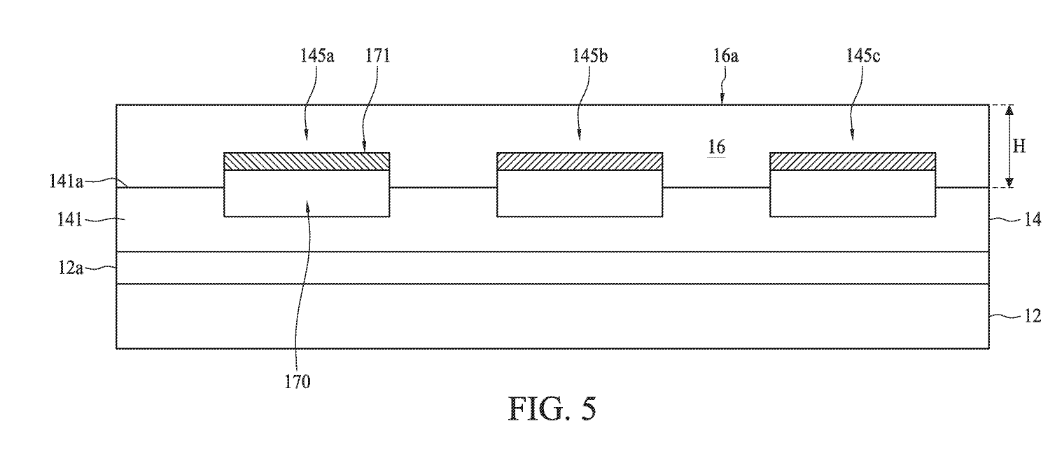

FIG. 5 illustrates the encapsulation layer 16 disposed over the light emitting layer 14. In some embodiments, the encapsulation layer 16 is directly in contact with the color filter 171. In some embodiments, the the encapsulation layer 16 is a polymeric material. In some embodiments, the encapsulation layer 16 includes graphene. In some embodiments, the encapsulation layer 16 includes fluorine. In some embodiments, the encapsulation layer 16 includes but not limited to PET, Polyimide, SiOx, SiNx, etc.

The encapsulation layer 16 has a thickness H, which is also a distance measured from the surface 141a to a top surface 16a of the encapsulation layer 16. In some embodiments, thickness H is between about 2 um and about 4 um. In some embodiments, thickness H is between about 4 um and about 6 um. 16. In some embodiments, thickness H is between about 6 um and about 8 um. 16. In some embodiments, thickness H is between about 8 um and about 10 um.

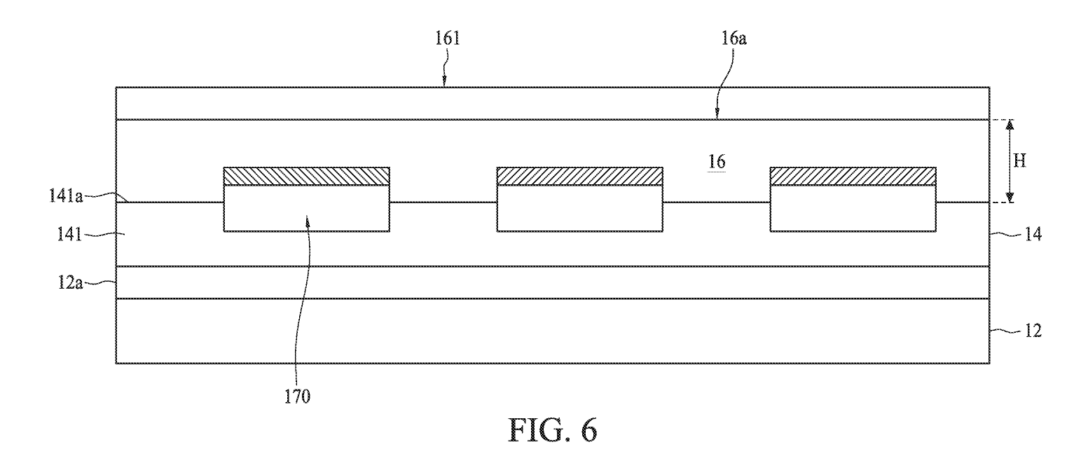

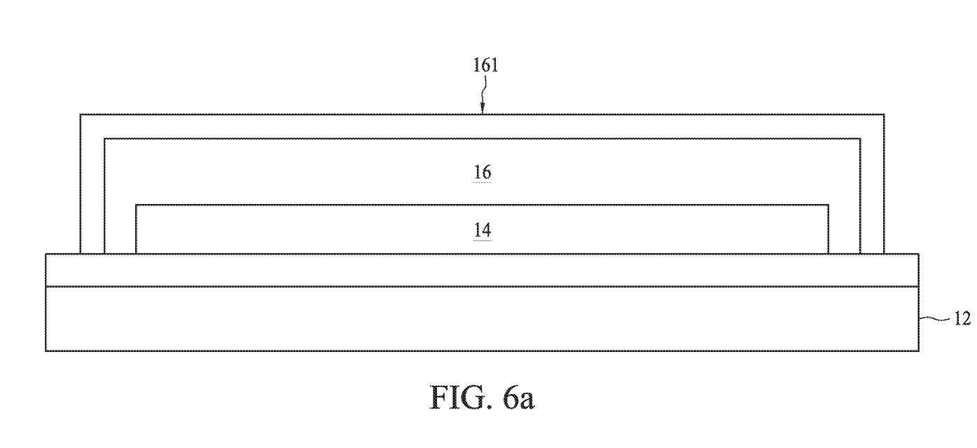

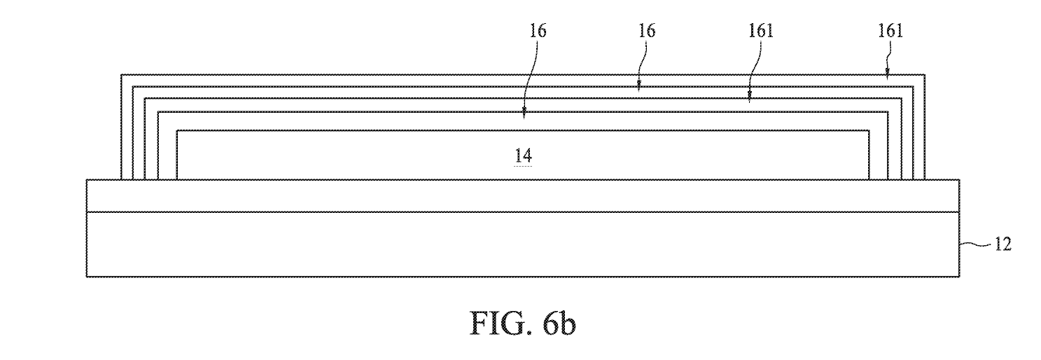

Top surface 16a is designed to be in contact with another film or layer. In some embodiments, a barrier layer 161 is disposed over the encapsulation layer 16 as in FIG. 6. In some embodiments, the barrier layer 161 is in contact with the top surface 16a of the encapsulation layer 16. In some embodiments, the barrier layer 161 has a hardness above 1H pencil hardness. In some embodiments, the barrier layer 161 has a hardness above 4H pencil hardness. In some embodiments, a hardness of the barrier layer 161 is about 10 times greater than that of the encapsulation layer 16.

In some embodiments, the barrier layer 161 has an Young's modulus between about 0.1 and about 4 Gpa. In some embodiments, the barrier layer 161 has an Young's modulus between about 0.1 and about 1 Gpa. In some embodiments, the barrier layer 161 has an Young's modulus between about 1 and about 2 Gpa. In some embodiments, the barrier layer 161 has an Young's modulus between about 2 and about 3 Gpa. In some embodiments, the barrier layer 161 has an Young's modulus between about 3 and about 4 Gpa.

In some embodiments, the barrier layer 161 can be an inorganic film. In some embodiments, the barrier layer 161 includes graphene. In some embodiments, the barrier layer 161 is includes but not limited to SiOx, SiNx, and their combination.

In one embodiment, the light emitting layer 14 is surrounded or sealed by the encapsulation layer 16 as illustrated in FIG. 6a. Further, the encapsulation layer 16 is surrounded or sealed by the barrier layer 161. For simplicity, the light emitting units are omitted in the drawing. In some embodiments, the encapsulation layer 16 and the barrier layer 161 are combined as a cap layer to surround and seal the light emitting layer 14.

FIG. 6b illustrates another embodiment showing a composite encapsulation structure is disposed on the light emitting layer 14. The composite encapsulation structure has two polymeric encapsulation layers 16 and two barrier layers 161 alternating arranged to cap the light emitting layer 14. However, the arrangement can have other different combinations. For example, a barrier layer 161 is disposed on the light emitting layer 14 then a polymeric encapsulation layers 16 followed by another barrier layer 161. In some embodiments, the composite encapsulation structure has more than two polymeric encapsulation layers 16 or more than two barrier layers 161.

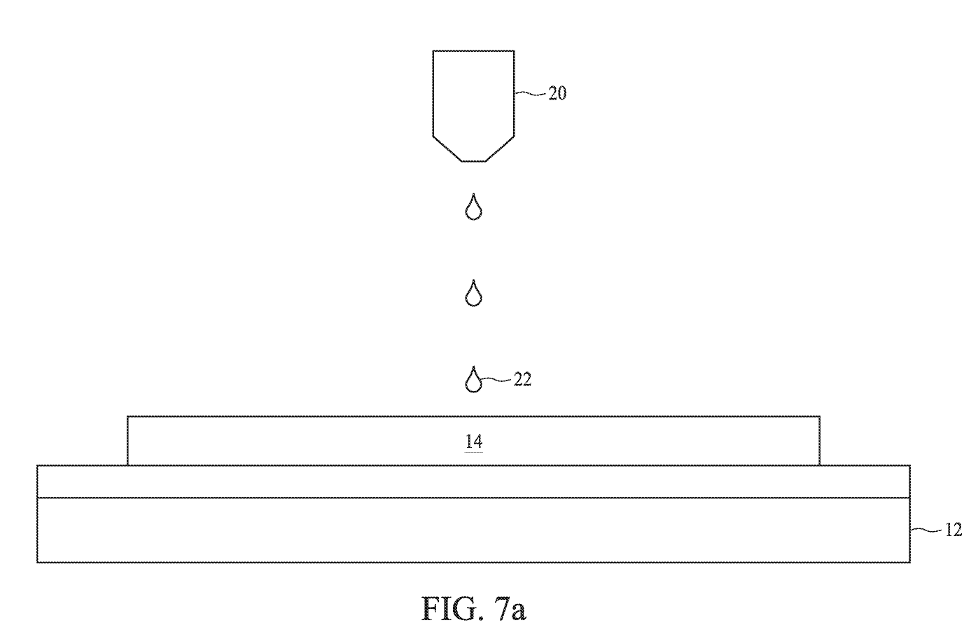

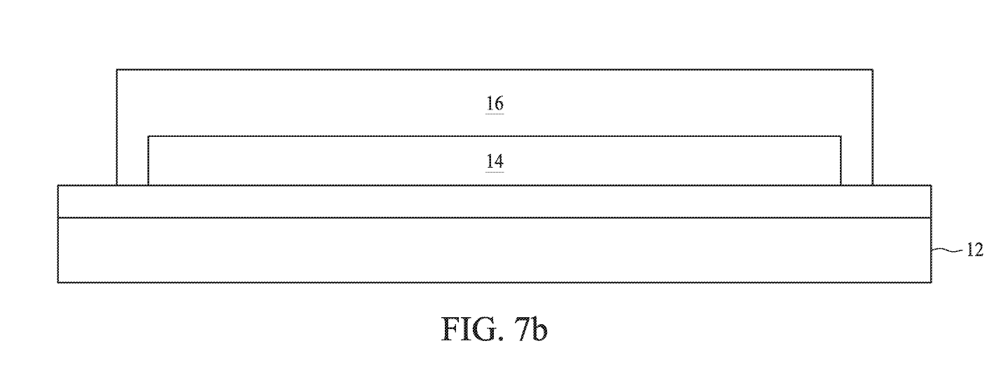

FIG. 7a illustrates an embodiment of spin coating the polymeric encapsulation layers 16 over the light emitting layer 14. Liquid drops 22 are dispensed from a nozzle 20. After the liquid drops 22 fall on the light emitting layer 14, the substrate 12 starts spinning and liquid drops 22 spray around the light emitting layer 14 to form a polymeric encapsulation layer 16 as shown in FIG. 7b. The encapsulation layer 16 can be formed with a single coat or multiple coat operation.

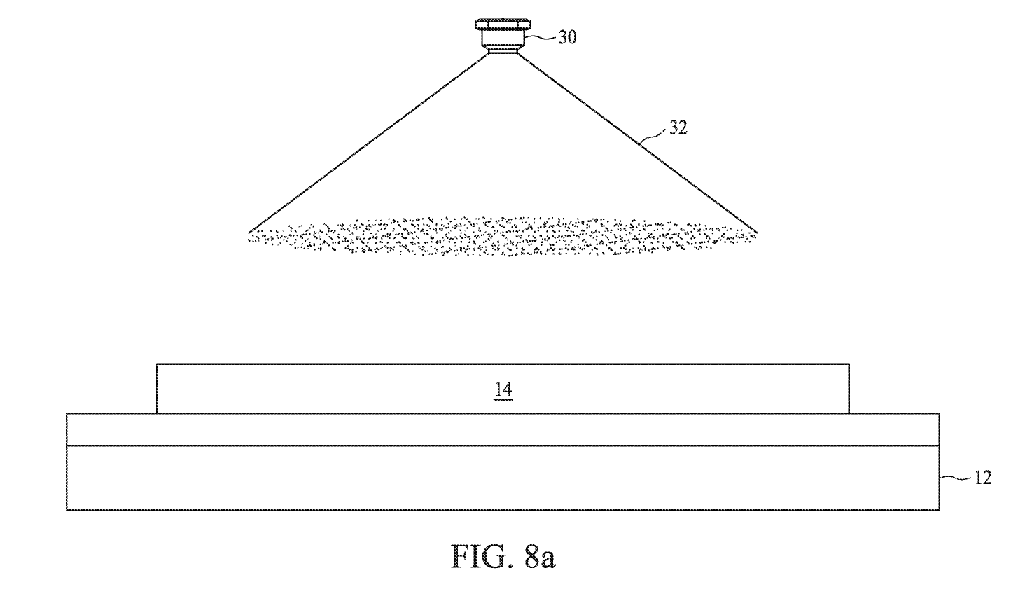

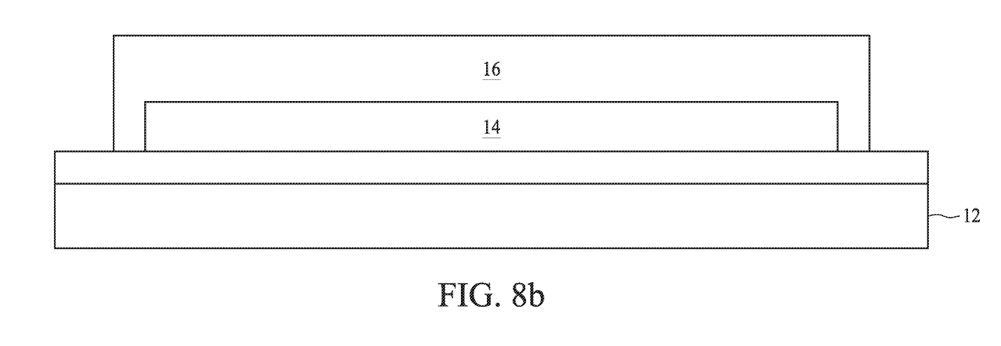

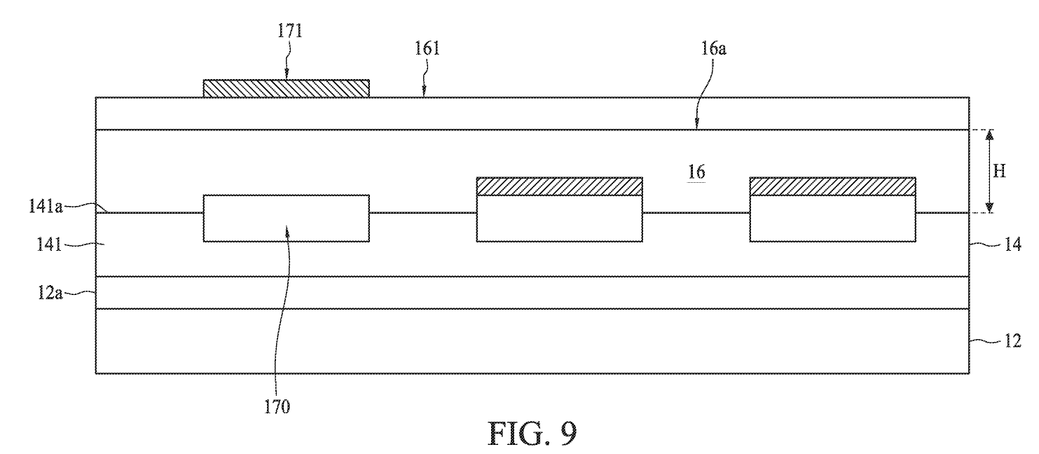

FIG. 8a illustrates an embodiment of jet spraying the polymeric encapsulation layers 16 over the light emitting layer 14. Liquid or gaseous drops 32 are dispensed from a nozzle 30. A polymeric encapsulation layer 16 is formed on the light emitting layer 14 as shown in FIG. 8b. The encapsulation layer 16 can be formed with a single spraying or multiple spraying operation.

In some embodiments, the color filter 171 is disposed over the light emitting cell 170 but separated by the polymeric encapsulation layers 16. In some embodiments, the color filter 171 is substantially aligned with the light emitting cell 170 from a top view perspective. Therefore, the interference to the light emitting cell 170 from ambient light can be effectively reduced. In some embodiments, a geometric center of the color filter 171 substantially coincides with a geometric center of the light emitting cell 170 from a top view perspective.

In some embodiments, the color filter can be disposed over a barrier layer 161. In some embodiments, the color filter can be disposed over a window layer 18 (please refer FIG. 1). In some embodiments, the color filter can be disposed over a touch panel layer (not in the drawings).

The foregoing outlines features of several embodiments so that persons having ordinary skill in the art may better understand the aspects of the present disclosure. Persons having ordinary skill in the art should appreciate that they may readily use the present disclosure as a basis for designing or modifying other devices or circuits for carrying out the same purposes or achieving the same advantages of the embodiments introduced therein. Persons having ordinary skill in the art should also realize that such equivalent constructions do not depart from the spirit and scope of the present disclosure, and that they may make various changes, substitutions and alternations herein without departing from the spirit and scope of the present disclosure.

1. A light emitting device, comprising:
a light emitting layer including:
a plurality of light emitting cells, configured to emit lights having a plurality of wavelength ranges; and
a plurality of color filters, wherein each of the plurality of color filters is over a corresponding one of the plurality of light emitting cells according to wavelength emitted by the corresponding one light emitting cell.

2. The light emitting device of claim 1, wherein a lateral width of one of the plurality of light emitting cells is not greater than about 5 μm.

3. The light emitting device of claim 1, wherein each of the plurality of light emitting cells is made with an organic light emitting material.

4. The light emitting device of claim 1, further comprising a substrate configured as a platform to have the light emitting layer disposed thereon, wherein one of the plurality of light emitting cells are in a recess of the substrate.

5. The light emitting device of claim 4, wherein one of the plurality of light emitting cells has a protrusion between about 0.2 μm and 2 μm measured from a top surface of the substrate.

6. The light emitting device of claim 1, wherein one of the plurality of color filters has a lateral width being substantially equal to that of the corresponding one light emitting cell.

7. The light emitting device of claim 1, wherein a geometric center of one of the plurality of color filters substantially coincides with a geometric center of the corresponding one light emitting cell.

8. The light emitting device of claim 1, wherein one of the plurality of color filters is in direct contact with the corresponding one light emitting cell.

9. The light emitting device of claim 1, wherein one of the plurality of color filters has a thickness between about 1 μm and about 20 μm.

10. The light emitting device of claim 1, further comprising a polymeric layer between one of the plurality of color filters and the corresponding one light emitting cell.

11. The light emitting device of claim 10, wherein the polymeric layer includes fluorine.

12. The light emitting device of claim 10, wherein the polymeric layer includes graphene.

13-20. (canceled)
